(19) United States
(12) Patent Application Publication
(10) Pub. No.: US 2008/0157069 A1
(43) Pub. Date: Jul. 3, 2008

(54) Thin film transistor for liquid crystal display device

(75) Inventors: Jae Seok Heo, Gyeonggi-do (KR); Woong Gi Jun, Gyeonggi-do (KR); Byung Geol Kim, Gyeonggi-do (KR)

Correspondence Address: SEYFARTH SHAW, LLP, 815 CONNECTICUT AVENUE, N.W., SUITE 500, WASHINGTON, DC, 20006, US

(73) Assignee: LG.PHILIPS LCD CO., LTD., Seoul (KR)

(21) Appl. No.: 12/003,179

(22) Filed: Dec. 20, 2007

(30) Foreign Application Priority Data
Dec. 28, 2006 (KR) 10-2006-0136660

(51) Int. Cl. H01L 51/05; H01L 29/786

(52) U.S. Cl. 257/40; 257/347; 257/E29.273; 257/E51.007

(57) ABSTRACT

A thin film transistor for an LCD device is disclosed, which comprises a gate electrode formed on a substrate; a gate insulation film formed of a high dielectric constant insulator having a bond structure of functional group, metal oxide, silicon and oxygen; and source and drain electrodes formed on the gate insulation film.

This application claims the benefit of Korean Patent Application No. 2006-136660 filed Dec. 28, 2006, which is hereby incorporated by reference in its entirety.

### BACKGROUND OF THE INVENTION

1. Field of the Invention

The present invention relates to a thin film transistor for a liquid crystal display (LCD) device.

2. Discussion of the Related Art

With the recent trend to low voltage, low power consumption, miniaturization, thin profile and light weight in various electronic devices based on the rapid development of semiconductor technology, there are many demands for flat panel display devices which are used as display devices of the electronic devices. Accordingly, the various flat panel display devices have been developed, for example, a liquid crystal display (LCD) device, a plasma display panel (PDP), and an organic light-emitting diode (OLED). Among these flat panel display devices, the LCD device has the greatest attentions owing to its excellencies in miniaturization, profile and lightness, and the low power consumption and driving voltage.

The LCD device is comprised of an upper substrate corresponding to a transparent insulation substrate including a common electrode, a color filter and a black matrix; a lower substrate corresponding to a transparent insulation substrate including a switching device and a pixel electrode; and a liquid crystal layer formed by injecting a liquid crystal material having an anisotropic dielectric constant to a space between the lower and upper substrates. According as different potentials are applied to the pixel electrode and the common electrode, it is possible to control an intensity of electric field formed in the liquid crystal material, thereby aligning liquid crystal molecules of the liquid crystal layer. Through the alignment of liquid crystal molecules, the amount of light passing through the transparent insulation substrate is controlled so that desired images are displayed thereon.

This LCD device is generally formed in a thin film transistor LCD device, which uses as a thin film transistor (TFT) as the switching device.

The thin film transistor is comprised of a substrate, a gate electrode, a gate insulation film, source and drain electrodes, and a semiconductor layer.

To fabricate the thin film transistor having the good electrical property such as high charge mobility, it is necessary to form the gate insulation film of high dielectric constant insulation material. However, if forming the gate insulation film of high dielectric constant insulation material, a leakage current of thin film transistor may be increased, thereby lowering the efficiency of thin film transistor.

### SUMMARY OF THE INVENTION

Accordingly, the present invention is directed to a thin film transistor for an LCD device that substantially obviates one or more problems due to limitations and disadvantages of the related art.

An object of the present invention is to provide a thin film transistor for an LCD device, provided with a gate insulation film of an insulation material having a high dielectric constant, which can realize high charge mobility and decrease leakage current.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a thin film transistor for LCD device comprises a gate electrode formed on a substrate; a gate insulation film formed of a high dielectric constant insulator having a bond structure of functional group, metal oxide, silicon and oxygen; and source and drain electrodes formed on the gate insulation film.

At this time, the silicon and metal oxide may be disposed at six vertexes, to form a ladder-type unit structure. Also, the silicon and metal oxide may be disposed at eight vertexes, to form a cage-type unit structure. Also, the silicon and metal oxide may be disposed at nine to eighteen vertexes, to form a cage-type unit structure.

Also, the high dielectric constant insulator is provided with a unit bond structure of metal oxide(Me)—oxygen(O)—metal oxide(Me), or a unit bond structure of silicon(Si)—oxygen(O)—silicon(Si).

The functional group is formed of any one of organic group, inorganic polymers, organic/inorganic hybrid polymer, single organic polymer, or complex organic polymer.

The metal oxide is formed of any one of Barium strontium titanate, Barium zirconate titanate, Lead zirconate titanate, Lead lanthanum titanate, Strontium titanate, Barium titanate, Barium magnesium fluoride, Bismuth titanate, Strontium bismuth tantalate, Strontium bismuth tanalate niobate, Al₂O₃, MgO, CaO, ZrSiO₄, HfSiO₄, Y₂O₃, ZrO₂, HfO₂, SrO, La₂O₃, Ta₂O₅, BaO, or TiO₂.

In addition, the thin film transistor comprises a semiconductor layer formed between the gate insulation film and the source/drain electrodes.

The semiconductor layer is formed of a silicon layer.

Also, the semiconductor layer is formed of an organic semiconductor layer which corresponds to any one of liquid crystalline polyfluorene block copolymer (LCPBC), pentacene or polythiophene.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a cross section view of illustrating a thin film transistor for an LCD device according to the present invention.

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

Hereinafter, a thin film transistor for an LCD device according to the present invention will be described with reference to the accompanying drawing.

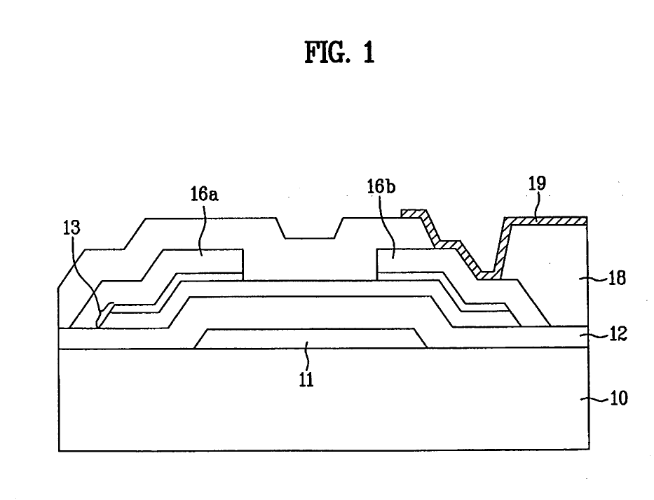

FIG. 1 is a cross section view of illustrating a thin film transistor for an LCD device according to the present invention.

As shown in FIG. 1, the thin film transistor is comprised of a gate electrode 11 formed on a transparent insulation substrate 10; a gate insulation film 12 formed of an insulation material having a high dielectric constant on the gate electrode 11; a semiconductor layer 13 formed on the gate insulation film 12, wherein the semiconductor layer 13 is comprised of an impurity amorphous silicon material which is highly doped with n-type impurities, and an amorphous silicon material which is not doped with impurities; and source and drain electrodes 16a and 16b, which expose a predetermined portion of the semiconductor layer 13 above the gate electrode 11, formed at a predetermined interval therebetween.

Then, a passivation layer 18 is formed on the source and drain electrodes 16a and 16b, wherein the passivation layer 18 is provided with a contact hole to expose the drain electrode 16b. Through the contact hole, a pixel electrode 19 is electrically connected with the drain electrode 16b.

In case of the thin film transistor having the aforementioned structure, the gate insulation film is formed of a high dielectric constant insulator which has a bond structure of functional group (R), metal oxide (Me), silicon (Si) and oxygen (O).

The high dielectric constant insulator, which is formed in the bond structure of functional group (R), metal oxide (Me), silicon (Si) and oxygen (O), has a dielectric constant of 8 or more.

The functional group (R) may be formed of any one of organic group, inorganic polymers (for example, polyphosphazene, polsiloxane, polysilzne, and etc.), organic/inorganic hybrid polymer, single organic polymer (for example, polyacrylate, polyimide, polyester), or complex organic polymer (for example, copolymer). Also, the metal oxide (Me) may be formed of any one of Barium strontium titanate, Barium zirconate titanate, Lead zirconate titanate, Lead lanthanum titanate, Strontium titanate, Barium titanate, Barium magnesium fluoride, Bismuth titanate, Strontium bismuth tantalate, Strontium bismuth tanalate niobate, Al₂O₃, MgO, CaO, ZrSiO₄, HfSiO₄, Y₂O₃, ZrO₂, HfO₂, SrO, La₂O₃, Ta₂O₅, BaO, or TiO₂.

At this time, the high dielectric constant insulator may be formed in a ladder-type unit structure which has a two-dimensional bond structure shown in chemical formula 1, or may be formed in a cage-type unit structure which has a three-dimensional bond structure shown in chemical formula 2.

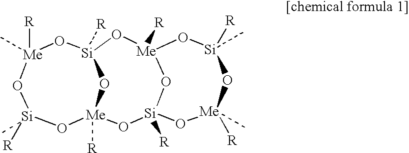

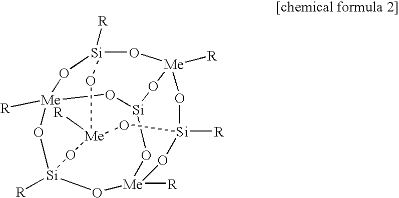

Accordingly, the ladder-type unit structure shown in chemical formula 1 is provided with three silicon (Si) atoms and three metal oxides (Me) disposed at respective vertexes, to form the unit bond of silicon(Si)—oxygen(O)—metal oxide(Me). The cage-type unit structure shown in chemical formula 2 is provided with four silicon (Si) atoms and four metal oxides (Me) disposed at respective vertexes, to form the unit bond structure of silicon(Si)—oxygen(O)—metal oxide(Me).

The hexahedral cage-type unit structure is formed with the four silicon (Si) atoms and four metal oxides (Me) respectively disposed at the eight vertexes. However, it is possible to provide a polyhedral cage-type unit structure which the silicon (Si) and metal oxides (Me) respectively disposed at the nine to eighteen vertexes.

As the metal oxides (Me) are increased in number, the dielectric constant is increased.

Also, both the ladder-type and cage-type unit structure disclose the unit structure of silicon(Si)—oxygen(O)—metal oxide(Me). However, the unit structure may be changed to silicon(Si)—oxygen(O)—silicon (Si) or metal oxide(Me)—oxygen(O)—metal oxide(Me).

The high dielectric constant insulator is applied to the thin film transistor for the LCD device including the semiconductor layer 13 of the silicon layer. However, the high dielectric constant insulator may be applied to an organic thin film transistor including an organic semiconductor layer. At this time, the organic semiconductor layer is formed of any one of liquid crystalline polyfluorene block copolymer (LCPBC), pentacene or polythiophene.

As mentioned above, the thin film transistor for the LCD device according to the present invention has the following advantages.

In case of the thin film transistor for the LCD device according to the present invention, the gate insulation film is formed of the high dielectric constant insulator having the bond structure of functional group (R), metal oxide (Me), silicon (Si) and oxygen (O), thereby realizing the high charge mobility and decreasing the leakage current of thin film transistor.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A thin film transistor for LCD device comprising:
a gate electrode formed on a substrate;
a gate insulation film formed of a high dielectric constant insulator having a bond structure of functional group, metal oxide, silicon and oxygen; and
source and drain electrodes formed on the gate insulation film.

2. The thin film transistor of claim 1, wherein the high dielectric constant insulator is provided with a unit bond structure of silicon(Si)—oxygen(O)—metal oxide(Me).

3. The thin film transistor of claim 2, wherein the silicon and metal oxide are disposed at six vertexes, to form a ladder-type unit structure.

4. The thin film transistor of claim 2, wherein the silicon and metal oxide are disposed at eight vertexes, to form a cage-type unit structure.

5. The thin film transistor of claim 2, wherein the silicon and metal oxide are disposed at nine to eighteen vertexes, to form a cage-type unit structure.

6. The thin film transistor of claim 1, wherein the high dielectric constant insulator is provided with a unit bond structure of metal oxide(Me)—oxygen(O)—metal oxide(Me).

7. The thin film transistor of claim 1, wherein the high dielectric constant insulator is provided with a unit bond structure of silicon(Si)—oxygen(O)—silicon(Si).

8. The thin film transistor of claim 1, wherein the functional group is formed of any one of organic group, inorganic polymer, organic/inorganic hybrid polymer, single organic polymer, or complex organic polymer.

9. The thin film transistor of claim 1, wherein the metal oxide is formed of any one of Barium strontium titanate, Barium zirconate titanate, Lead zirconate titanate, Lead lanthanum titanate, Strontium titanate, Barium titanate, Barium magnesium fluoride, Bismuth titanate, Strontium bismuth tantalate, Strontium bismuth tanalate niobate, Al₂O₃, MgO, CaO, ZrSiO₄, HfSiO₄, Y₂O₃, ZrO₂, HfO₂, SrO, La₂O₃, Ta₂O₅, BaO, or TiO₂.

10. The thin film transistor of claim 1, further comprising a semiconductor layer formed between the gate insulation film and the source/drain electrodes.

11. The thin film transistor of claim 10, wherein the semiconductor layer is formed of a silicon layer.

12. The thin film transistor of claim 10, wherein the semiconductor layer is formed of an organic semiconductor layer which corresponds to any one of liquid crystalline polyfluorene block copolymer (LCPBC), pentacene or polythiophene.
